(19) United States
(12) Patent Application Publication
(10) Pub. No.: US 2014/0273465 A1
(43) Pub. Date: Sep. 18, 2014

(54) METHOD OF FORMING DUAL GATE OXIDE

(71) Applicant: Shanghai Huali Microelectronics Corporation, Shanghai (CN)

(72) Inventor: Zhibiao MAO, Shanghai (CN)

(73) Assignee: Shanghai Huali Microelectronics Corporation, Shanghai (CN)

(21) Appl. No.: 14/056,064

(22) Filed: Oct. 17, 2013

(30) Foreign Application Priority Data
Mar. 15, 2013 (CN) 201310084516.4

(51) Int. Cl. H01L 21/02

(52) U.S. Cl. CPC H01L 21/02164
USPC 438/701

(57) ABSTRACT

A method of forming a dual gate oxide is disclosed which includes: providing a silicon substrate; depositing a first silicon oxide film over the silicon substrate; coating a photoresist over the first silicon oxide film; exposing and developing the photoresist to expose a portion of the first silicon oxide film; coating a crosslinking agent containing amine compound or polyamine compound on the photoresist and performing a heat curing process, thereby forming a protective layer of crosslinked macromolecules over the photoresist; removing the remaining crosslinking agent; performing a wet etching process to reduce a thickness of, or completely remove, the exposed portion of the first silicon oxide film; removing the photoresist and the protective layer formed thereon; and depositing a second silicon oxide film.

### CROSS-REFERENCES TO RELATED APPLICATIONS

This application claims the priority of Chinese patent application number 201310084516.4, filed on Mar. 15, 2013, the entire contents of which are incorporated herein by reference.

### TECHNICAL FIELD

The present invention, relates generally to the fabrication of semiconductor conductor devices, and more particularly, to a method of forming dual gate oxide.

### BACKGROUND

An advanced integrated circuit chip, in general, contains a variety of functional devices. Each functional device corresponds to certain field-effect transistors (FETs). In order to form the integration of different FETs in a single chip, multi-gate oxide processes are commonly employed, and currently, there are a number of methods available to form multiple gate oxide.

For instance, FIGS. 1-4 show the steps of a conventional dual gate oxide process which includes first coating photoresist 4 on a silicon oxide film 3 deposited over a silicon substrate 1 in which shallow isolation trenches 2 are formed (refer to FIG. 1). After exposure and development processes, a portion of the photoresist 4 is removed, exposing a region 5 of the underlying silicon oxide film 3, where a wet etching process is to be subsequently performed, and leaving a region 6 of the silicon oxide film 3 still covered by the rest of the photoresist 4 (refer to FIG. 2). Next, a partial thickness of the silicon oxide film 3 in region 5 is removed (refer to FIG. 3a) or the silicon oxide film 3 in region 5 is totally removed (refer to FIG. 3b) using a wet etching process. After that, the remaining photoresist 4 is removed, selectively followed by the deposition of another thickness of silicon oxide over the resulting structure, thereby forming the silicon oxide film 3 into a silicon oxide layer with different thicknesses in different regions 5 and 6, namely, a so-called “dual gate oxide” (refer to FIG. 4).

The wet etching process for etching the silicon oxide film 3 can include placing the silicon substrate 1 on which the silicon oxide film 3 has been deposited into an acidic solution. The acidic solution commonly used in this process is hydrofluoric acid (HF). However, accompanying with its etching effect on the silicon oxide film 3, the acidic solution also influences the photoresist 4 and causes defects therein, mainly including photoresist residues and silicon carbide (SiC) deposits. The occurrence of photoresist residues is because the encroachment of the acidic solution dissociates certain macromolecular compounds from the photoresist, which thereafter precipitate to surface of the silicon substrate. SiC deposits are composed of SiC particles generated from the reaction between macromolecular compounds and silicon hexafluoride (SiF6) which is a product of the reaction of HF and silicon oxide.

Currently, there have been several methods available to prevent the occurrence of photoresist defects in the wet etching process. One method is to bake the exposed and developed photoresist into a densified form with narrower gaps between macromolecules contained therein, which block entry of the acidic solution into the photoresist during the wet etching process. Another method utilizes ultraviolet (UV) light or plasma to cure the exposed and developed photoresist to create inter-macromolecular crosslinks on the surface thereof, which can effectively strengthen the ability of the photoresist to resist the encroachment of the acidic solution. U.S. Pat. No. 6,498,106B1 describes the invention of a method for preventing the occurrence of photoresist defects during a wet etching process using a low-energy plasma curing treatment.

However, these photoresist-defect prevention methods of the prior art each suffer from a number of deficiencies. One deficiency is that, in the baking method, the baking step should not be performed at an excessively high temperature for too long, otherwise, the photoresist pattern will deform, thus adversely affecting production throughput. On the other hand, limited baking temperature and duration may lead to the baked photoresist having an insufficient density to resist the encroachment of the acidic solution. Another deficiency lies in that the surface-curing method requires a UV or plasma treatment after the photolithographic process, which needs to be performed on other equipment and hence leads to disadvantages, such as increasing process cost, elongating production cycle and reducing production throughput.

### SUMMARY OF THE INVENTION

The present invention addresses the prior art problems by presenting a method for preventing the occurrence of photoresist defects during a wet etching process. The method enables the photoresist to gain sufficient resistance against the acidic solution while not affecting production throughput.

According to a first aspect of the invention, the foregoing object is attained by a method of forming a dual gate oxide, including: providing a silicon substrate; depositing a first silicon oxide film over the silicon substrate; coating a photoresist over the first silicon oxide film; exposing and developing the photoresist to expose a portion of the first silicon oxide film; coating a crosslinking agent containing amine compound or polyamine compound on the photoresist and performing a heat curing process thereon to form a protective layer of crosslinked macromolecules over the photoresist; removing the remaining crosslinking agent; performing a wet etching process to reduce a thickness of the exposed portion of the first silicon oxide film; removing the photoresist and the protective layer; and depositing a second silicon oxide film.

According to a second aspect of the invention, the foregoing object is also attained by a method of forming a dual gate oxide, including: providing a silicon substrate; depositing a first silicon oxide film over the silicon substrate; coating a photoresist over the first silicon oxide film; exposing and developing the photoresist to expose a portion of the first silicon oxide film; coating a crosslinking agent containing amine compound or polyamine compound on the photoresist and performing a heat curing process thereon to form a protective layer of crosslinked macromolecules over the photoresist; removing the remaining crosslinking agent; performing a wet etching process to completely remove the exposed portion of the first silicon oxide film; removing the photoresist and the protective layer; and depositing a second silicon oxide film.

Preferably, coating the crosslinking agent may be performed in a developing apparatus for developing the photoresist.

Preferably, removing the remaining crosslinking agent may include: treating the remaining crosslinking agent with an acidic solution; and removing the remaining crosslinking agent with a deionized water.

Preferably, the acidic solution may contain an acidic compound selected from the group consisting of polyacrylic acid, polymethacrylic acid, polyvinyl sulfonic acid, alkyl carboxylic acids, aryl carboxylic acids, alkyl sulfonic acids and aryl sulfonic acids, and the acidic compound may have a concentration by weight of 0.5% to 20%.

Preferably, the amine compound or polyamine compound has a concentration by weight of 0.1% to 100% in the crosslinking agent.

Preferably, the crosslinking agent may further include at least one of a crosslinking catalyst and a surfactant.

Preferably, the crosslinking catalyst may be an organic solvent-soluble non-nucleophilic tertiary amine and may have a concentration by weight of 0.1% to 20%.

Preferably, the surfactant may be an organic solvent-soluble non-ionic surfactant and may have a concentration of 50 ppm to 10000 ppm.

Preferably, the heat curing process may be performed at a temperature of 30° C. to 180° C. for 15 seconds to 300 seconds.

Preferably, the silicon substrate may include a plurality of shallow trench isolation structures formed therein.

### BRIEF DESCRIPTION OF THE DRAWINGS

A more complete appreciation of the invention and the attendant advantages and features thereof will be readily obtained as the same becomes better understood by reference to the following detailed description when considered in connection with the accompanying drawings, wherein:

FIGS. 1, 2, 3a, 3b, and 4 schematically illustrate the steps of a method of forming a dual gate oxide in accordance with the prior art;

FIGS. 5a-5e schematically illustrate the steps of a method of forming a dual gate oxide in accordance with Embodiment 1 of the present invention; and

FIGS. 6a-6e schematically illustrate the steps of a method of forming a dual gate oxide in accordance with Embodiment 2 of the present invention.

Note that the figures of the accompanying drawings are illustrative only and are not intended to limit the scope of the present invention, and they may not be drawn precisely to scale. Same or analogous reference numbers in the various drawings indicate like elements.

### DETAILED DESCRIPTION

The present invention will become more apparent and fully understood, from the following detailed description of exemplary embodiments thereof, which is to be read in connection with the accompanying drawings.

### Embodiment 1

This embodiment provides a method, of forming a dual gate oxide described in detail below, wherein a dual gate oxide refers to a gate oxide layer having at least two portions with different thicknesses.

Referring to FIG. 5a, in the method, photoresist 4 is first coated over a silicon oxide film 3 deposited on a silicon substrate 1 in which a number of shallow trench isolation (STI) structures 2 have been formed. The photoresist can be used include those for use in I-line, 248 nm, 193 nm and extreme ultraviolet (EUV) photolithographic processes.

Next, as shown in FIG. 5b, the photoresist 4 is exposed and developed, thereby exposing a portion of the underlying silicon oxide film 3 for receiving a subsequent wet etching process, referred to hereinafter as “the first silicon oxide region” indicated at 5, with the rest portion of the silicon oxide film 3, referred to hereinafter as “the second silicon oxide region” indicated at 6, being protected by the remaining photoresist 4.

After the exposure and development, in an identical developing apparatus where the photoresist 4 was developed, a crosslinking agent containing amine compound or polyamine compound is coated on the remaining photoresist 4 and is heated to induce a reaction between the amine compound or polyamine compound and a surface portion of the photoresist 4, which results in a protective layer 70f crosslinked macromolecules, as shown in FIG. 5c, which solidifies the remaining photoresist 4. After that, the remaining crosslinking agent is removed by, for example, first treating the remaining crosslinking agent with an acidic solution and then removing the remaining crosslinking agent with deionized water.

Preferably, the major ingredient of the crosslinking agent is the amine compound or polyamine compound, and other ingredients may include, but not limited to, at least one of a crosslinking catalyst and a surfactant.

Preferably, the amine compound or polyamine compound may have a concentration by weight of 0.1% to 100%, more preferably, of 0.5% to 10%, in the crosslinking agent.

Preferably, the crosslinking catalyst may be selected based on the crosslinking reactivity, such as an organic solvent-soluble non-nucleophilic tertiary amine with a concentration by weight of 0.1% to 20%, more preferably, of 0.5% to 5%.

Preferably, the surfactant may be selected based on the solubility and reactivity of the crosslinking agent, such as an organic solvent-soluble non-ionic surfactant with a concentration of 50 ppm to 10000 ppm, more preferably, of 100 ppm to 1000 ppm.

Preferably, the acidic solution may contain, but not limited to, an acidic compound selected from the group consisting of polyacrylic acid, polymethacrylic acid, polyvinyl sulfonic acid, alkyl carboxylic acids, aryl carboxylic acids, alkyl sulfonic acids and aryl sulfonic acids, and the acidic solution may have a concentration by weight of 0.5% to 20%, more preferably, of 1% to 10%.

Preferably, the crosslinking agent may be heated at a temperature of 30° C. to 180° C., more preferably, of 50° C. to 120° C., for 15 seconds to 300 seconds, more preferably, for 30 seconds to 120 seconds.

After that, referring to FIG. 5d, a wet etching process is performed to remove a partial thickness of the first silicon oxide region 5.

Next, as seen in FIG. 5e, after the photoresist 4 and protective layer 7 formed thereon are removed, another silicon oxide film 3 may be selectively deposited over the resulting structure, thereby forming a dual gate oxide with different thicknesses in the first and second silicon oxide regions 5 and 6.

After the above described steps of the method, subsequent processes can be performed to form different field-effect transistors (FETs) in the two silicon oxide regions.

### Embodiment 2

This embodiment provides another method of forming a dual gate oxide described in detail below, wherein a dual gate oxide refers to a gate oxide layer having at least two portions with different thicknesses.

Referring to FIG. 6a, in the method, photoresist 4 is coated over a silicon oxide film 3 deposited on a silicon substrate 1 in which a number of shallow trench isolation (STI) structures 2 have been formed. The photoresist can be used include those for use in I-line, 248 nm, 193 nm and extreme ultraviolet (EUV) photolithographic processes.

Next, as shown in FIG. 6b, the photoresist 4 is exposed and developed in a developing apparatus, thereby exposing a portion of the underlying silicon oxide film 3 for receiving a subsequent wet etching process, referred to hereinafter as “the first silicon oxide region” indicated at 5, with the rest portion of the silicon oxide film 3, referred to hereinafter as “the second silicon oxide region” indicated at 6, being protected by the remaining photoresist 4.

After that, in the same developing apparatus, in an identical developing apparatus where the photoresist 4 was developed, a crosslinking agent containing amine compound or polyamine compound is coated on the remaining photoresist 4 and is heated to induce a reaction between the amine compound or polyamine compound and a surface portion of the photoresist 4, which results in a protective layer 7 of crosslinked macromolecules, as shown in FIG. 6c, which solidifies the remaining photoresist 4. Next, the remaining crosslinking agent is removed by, for example, first treating the remaining crosslinking agent with an acidic solution and then removing the remaining crosslinking agent with deionized water.

Preferably, the major ingredient of the crosslinking agent is the amine compound or polyamine compound, and other ingredients may include, but not limited to, at least one of a crosslinking catalyst and a surfactant.

Preferably, the amine compound or polyamine compound may have a concentration by weight of 0.1% to 100%, more preferably, of 0.5% to 10%, in the crosslinking agent.

Preferably, the crosslinking catalyst may be selected based on the crosslinking reactivity, such as an organic solvent-soluble non-nucleophilic tertiary amine with a concentration by weight of 0.1% to 20%, more preferably, of 0.5% to 5%.

Preferably, the surfactant may be selected based on the solubility and reactivity of the crosslinking agent, such as an organic solvent-soluble non-ionic surfactant with a concentration of 50 ppm to 10000 ppm, more preferably, of 100 ppm to 1000 ppm.

Preferably, the acidic solution may contain, but not limited to, an acidic compound selected from the group consisting of polyacrylic acid, polymethacrylic acid, polyvinyl sulfonic acid, alkyl carboxylic acids, aryl carboxylic acids, alkyl sulfonic acids and aryl sulfonic acids, and the acidic solution may have a concentration by weight of 0.5% to 20%, more preferably, of 1% to 10%.

Preferably, the crosslinking agent may be heated at a temperature of 30° C. to 180° C., more preferably, of 50° C. to 120° C., for 15 seconds to 300 seconds, more preferably, for 30 seconds to 120 seconds.

After that, referring to FIG. 6d, a wet etching process is performed to completely remove the first silicon oxide region 5.

Next, as seen in FIG. 6e, after the photoresist 4 and protective layer 7 formed thereon are removed, another silicon oxide film 3 is deposited over the resulting structure, thereby forming a dual gate oxide with different thicknesses in the first and second silicon oxide regions 5 and 6.

After the above described steps of the method, subsequent processes can be performed to form different field-effect transistors (FETs) in the two silicon oxide regions.

With the methods of the above described embodiments, density of the photoresist 4 in a surface portion can be effectively increased, resulting in an improvement in the anti-acidic solution capability of the photoresist 4. Accordingly, the occurrence possibility of defects in the photoresist 4 during the wet etching process can be decreased without needing additional equipment, thus reducing necessary process steps and process cost, and improving productivity.

By chemically curing the photoresist pattern using the amine or polyamine compound in the same developing apparatus where the photoresist is developed to form the photoresist pattern, thereby forming the surface of the photoresist 4 into the protective layer 7 of crosslinked macromolecules, the methods of the present invention address the prior art problems by enabling the photoresist to gain a sufficient resistance against the acidic solution while not affecting production throughput.

It should be noted that, as used herein, unless otherwise specified or noted, the terms such as “first”, “second” and “third” are terms to distinguish different components, elements, steps, etc. described in the disclosure, not terms to describe logical or ordinal relationships among the individual components, elements, steps, etc.

It is to be understood that while preferred embodiments have been presented in the foregoing description of the invention, they are not intended to limit the invention in any way. Those skilled in the art can make various equivalent alternatives, modifications and variations to the preferred embodiments in light of the above teachings without departing from the scope of the invention. Thus, it is intended that the present invention covers all such simple modifications, equivalent alternatives and variations.

What is claimed is:

1. A method of forming a dual gate oxide, comprising:
providing a silicon substrate;
depositing a first silicon oxide film over the silicon substrate;
coating a photoresist over the first silicon oxide film;
exposing and developing the photoresist to expose a portion of the first silicon oxide film;
coating a crosslinking agent containing amine compound or polyamine compound on the photoresist and performing a heat curing process thereon to form a protective layer of crosslinked macromolecules over the photoresist;
removing the remaining crosslinking agent;
performing a wet etching process to reduce a thickness of the exposed portion of the first silicon oxide film;
removing the photoresist and the protective layer; and
depositing a second silicon oxide film.

2. The method of claim 1, wherein coating the cross linking agent is performed in a developing apparatus for developing the photoresist.

3. The method of claim 1, wherein removing the remaining crosslinking agent includes: treating the remaining crosslinking agent with an acidic solution; and removing the remaining crosslinking agent with a deionized water.

4. The method of claim 3, wherein the acidic solution contains an acidic compound selected from the group consisting of polyacrylic acid, polymethacrylic acid, polyvinyl sulfonic acid, alkyl carboxylic acids, aryl carboxylic acids, alkyl sulfonic acids and aryl sulfonic acids, the acidic compound having a concentration by weight of 0.5% to 20%.

5. The method of claim 1, wherein the amine compound or polyamine compound has a concentration by weight of 0.1% to 100% in the crosslinking agent.

6. The method of claim 1, wherein the crosslinking agent further includes at least one of a crosslinking catalyst and a surfactant.

7. The method of claim 6, wherein the crosslinking catalyst is an organic solvent-soluble non-nucleophilic tertiary amine and has a concentration by weight of 0.1% to 0.20%.

8. The method of claim 6, wherein the surfactant is an organic solvent-soluble non-ionic surfactant and has a concentration of 50 ppm to 10000 ppm.

9. The method of claim 1, wherein the heat curing process is performed at a temperature of 30° C. to 180° C. for 15 seconds to 300 seconds.

10. The method of claim 1, wherein a plurality of shallow trench isolation structures are formed in the silicon substrate.

11. A method of forming a dual gate oxide, comprising:
providing a silicon substrate;
depositing a first silicon oxide film over the silicon substrate;
coating a photoresist over the first silicon oxide film;
exposing and developing the photoresist to expose a portion of the first silicon oxide film;
coating a crosslinking agent containing amine compound or polyamine compound on the photoresist and performing a heat curing process thereon to form a protective layer of crosslinked macromolecules over the photoresist;
removing the remaining crosslinking agent;
performing a wet etching process to completely remove the exposed portion of the first silicon oxide film;
removing the photoresist and the protective layer; and
depositing a second silicon oxide film.

12. The method of claim 11, wherein coating the crosslinking agent is performed in a developing apparatus for developing the photoresist.

13. The method of claim 11, wherein removing the remaining crosslinking agent includes: treating the remaining crosslinking agent with an acidic solution; and removing the remaining crosslinking agent with a deionized water.

14. The method of claim 13, wherein the acidic solution contains an acidic compound selected from the group consisting of polyacrylic acid, polymethacrylic acid, polyvinyl sulfonic acid, alkyl carboxylic acids, aryl carboxylic acids, alkyl sulfonic acids and aryl sulfonic acids, the acidic compound having a concentration by weight of 0.5% to 20%.

15. The method of claim 11, wherein the crosslinkable amine or polyamine compound has a concentration by weight of 0.1% to 100% in the crosslinking agent.

16. The method of claim 11, wherein the crosslinking agent further includes at least one of a crosslinking catalyst and a surfactant.

17. The method of claim 16, wherein the crosslinking catalyst is an organic solvent-soluble non-nucleophilic tertiary amine and has a concentration by weight of 0.1% to 20%.

18. The method of claim 16, wherein the surfactant is an organic solvent-soluble non-ionic surfactant and has a concentration of 50 ppm to 10000 ppm.

19. The method of claim 11, wherein the heat curing process is performed at a temperature of 30° C. to 180° C. for 15 seconds to 300 seconds

20. The method of claim 11, wherein a plurality of shallow trench isolation structures are fondled in the silicon substrate.
